(19) United States
(12) Patent Application Publication
(10) Pub. No.: US 2026/0223582 A1
(43) Pub. Date: Jul. 30, 2026

(54) DISPLAY PANEL, METHOD FOR PREPARING DISPLAY PANEL, AND DISPLAY DEVICE

(71) Applicant: Guangzhou China Star Optoelectronics Semiconductor Display Technology Co., Ltd., Guangzhou (CN)

(72) Inventors: Xiaolin YAN, Guangzhou (CN); Bin ZHAO, Guangzhou (CN); Juncheng XIAO, Guangzhou (CN); Jun ZHAO, Guangzhou (CN); Qianhui SUN, Guangzhou (CN); Xiaoxing ZHANG, Guangzhou (CN)

(73) Assignee: Guangzhou China Star Optoelectronics Semiconductor Display Technology Co., Ltd., Guangzhou (CN)

(21) Appl. No.: 19/243,003

(22) Filed: Jun. 19, 2025

(30) Foreign Application Priority Data
Jan. 24, 2025 (CN) 202510121539.0

(51) Int. Cl. H10K 59/80; H10D 86/40; H10D 86/60; H10K 59/12

(52) U.S. Cl. CPC H10K 59/8792; H10D 86/423; H10D 86/60; H10K 59/1201

(57) ABSTRACT

A display panel, a method for preparing a display panel, and a display device are provided. The display panel includes a substrate, a light shielding layer, a second electrode plate, a first source-drain layer and a second source-drain layer, the light shielding layer includes a first electrode plate, the first source-drain layer includes a conductive electrode, the second source-drain layer is disposed on a side of the first source-drain layer away from the substrate, and the second source-drain layer includes a third electrode plate. The third electrode plate is used as a capacitor electrode, the third electrode plate is extended toward a direction of the second electrode plate, and the third electrode plate is electrically connected to the first electrode plate through the conductive electrode, so that the third electrode plate, the second electrode plate and the first electrode plate are overlapped to form a capacitor.

### CROSS-REFERENCE TO RELATED APPLICATION

This application claims priority to and the benefit of Chinese Patent Application No. 202510121539.0, filed on January 24, 2025, the disclosure of which is incorporated herein by reference in its entirety.

### TECHNICAL FIELD

The present disclosure relates to the field of display technology, and in particular, to a display panel, a method for preparing a display panel, and a display device.

### BACKGROUND

In the field of display technology, liquid crystal display (LCD) technology and active matrix organic light-emitting diode (AMOLED) display technology have been widely used because of many advantages such as thin body, high image quality, power saving, and no radiation.

At present, the liquid crystal display panel and organic light-emitting diode display panel have a large number of film layers and need a large number of masks due to their complex structures, which will not only increase time costs and material costs, but also lead to low process yield of the display panel.

Therefore, it is necessary to provide a display panel, a method for preparing a display device, and a display device to address this defect.

### SUMMARY

Embodiments of the present disclosure provide a display panel, a method for preparing the display panel, and a display device, which can simplify the structure of the display panel, improve the manufacturing process yield of the display panel, and reduce the production cost of the display panel.

To achieve the above object, a first aspect of the present disclosure provides a display panel including:

a substrate;

a light shielding layer disposed on one side of the substrate, the light shielding layer includes a first electrode plate;

a second electrode plate disposed on a side of the light shielding layer away from the substrate;

a first source-drain layer disposed on the side of the light shielding layer away from the substrate, the first source-drain layer includes a conductive electrode; and

a second source-drain layer disposed on a side of the first source-drain layer away from the substrate;

the second source-drain layer includes a third electrode plate, the third electrode plate is extended toward a direction of the second electrode plate, the third electrode plate is electrically connected to the first electrode plate through the conductive electrode, and along a thickness direction of the display panel, the third electrode plate, the second electrode plate and the first electrode plate are overlapped to form a capacitor.

Optionally, the display panel further includes a passivation layer, the passivation layer is disposed on the side of the first source-drain layer away from the substrate, a portion of the passivation layer corresponding to the second electrode plate is recessed toward the direction of the second electrode plate and forms a groove, and the third electrode plate is partially disposed in the groove.

Optionally, the third electrode plate include:

a body portion disposed at a bottom portion of the groove;

a first connecting portion disposed on a sidewall of the groove, the first connecting portion is connected to the body portion; and

a second connecting portion disposed on the passivation layer at a periphery of the groove, one end of the second connecting portion is connected to the first connecting portion, and another end of the second connecting portion is connected to the conductive electrode.

Optionally, the display panel further includes an interlayer dielectric layer, the interlayer dielectric layer is partially disposed between the second electrode plate and the first source-drain layer, a first opening is formed on a portion of the interlayer dielectric layer corresponding to the second electrode plate, the passivation layer is continuously disposed along a bottom portion and a sidewall of the first opening, and is recessed above the first opening to form the groove.

Optionally, the display panel further includes a first planarization layer, the first planarization layer is disposed on the passivation layer, and the second source-drain layer is partially disposed on the first planarization layer;

a second opening is formed on a portion of the first planarization layer corresponding to the third electrode plate, and an orthographic projection of the third electrode plate on the substrate is in an orthographic projection of the second opening on the substrate.

Optionally, the display panel further includes a second planarization layer, the planarization layer is disposed on the first planarization layer and the second source-drain layer, and fills the second opening.

Optionally, a material of the first planarization layer includes polyimide, and a material of the second planarization layer includes acrylate.

Optionally, the display panel further includes a first active layer, the first active layer is disposed on the side of the light shielding layer away from the substrate, a material of the first active layer includes an oxide semiconductor material, and the first active layer includes the second electrode plate.

Optionally, the display panel further includes:

a first active layer disposed on the side of the light shielding layer away from the substrate, and a material of the first active layer includes an oxide semiconductor material; and

a gate layer disposed on a side of the first active layer away from the substrate, the gate layer includes the second electrode plate.

optionally, the display panel further includes:

a first gate insulating layer disposed on the substrate and the first active layer;

a second active layer disposed on the first gate insulating layer, a material of the second active layer includes a silicon semiconductor material; and

a second gate insulating layer disposed on the first gate insulating layer and the second active layer, the gate layer is disposed on the second gate insulating layer;

the first gate insulating layer and the second gate insulating layer are partially disposed between the second electrode plate and the first electrode plate.

optionally, the display panel further includes:

a first active layer disposed on the side of the light shielding layer away from the substrate, and the first active layer includes the second electrode plate; and

a gate layer disposed on a side of the first active layer away from the substrate, the gate layer includes a fourth electrode plate, and along a thickness direction of the display panel, the third electrode plate, the fourth electrode plate, the second electrode plate, and the first electrode plate are overlapped to form the capacitor.

optionally, the display panel further includes:

a first gate insulating layer disposed on the substrate and the first active layer;

a second active layer disposed on the first gate insulating layer; and

a second gate insulating layer disposed on the first gate insulating layer and the second active layer, the gate layer is disposed on the second gate insulating layer;

the first gate insulating layer and the second gate insulating layer are partially disposed between the second electrode plate and the fourth electrode plate.

Optionally, the display panel includes a display area and a gate driving circuit area disposed at a periphery of the display area, the gate driving circuit area is provided with a gate driving circuit, the second source-drain layer includes a signal bus, and the signal bus is disposed in the gate driving circuit area.

Optionally, the display area is provided with a plurality of first transistors, and the gate driving circuit includes a plurality of second transistors;

each of the plurality of first transistors includes a first active portion, and a material of the first active portion includes an oxide semiconductor material; each of the plurality of second transistor includes a second active portion, and a material of the second active portion includes an oxide semiconductor material or a silicon semiconductor material.

According to a second aspect of the present disclosure, a method for preparing a display panel for manufacturing the display panel described above is provided, and the method for preparing a display panel includes the following steps:

forming the light shielding layer on the substrate, and the light shielding layer includes the first electrode plate;

forming the second electrode plate on the side of the light shielding layer away from the substrate; and

forming the first source-drain layer and the second source-drain layer on the side of the light-shielding layer away from the substrate, the first source-drain layer includes the conductive electrode, and the second source-drain layer includes the third electrode plate;

the third electrode plate is extended toward the direction of the second electrode plate, the third electrode plate is electrically connected to the first electrode plate through the conductive electrode, and along the thickness direction of the display panel, the third electrode plate, the second electrode plate and the first electrode plate are overlapped to form the capacitor.

Optionally, forming the first source-drain layer and the second source-drain layer on the side of the light-shielding layer away from the substrate includes following steps:

forming an interlayer dielectric layer on the side of the light shielding layer away from the substrate, a first opening is formed on the interlayer dielectric layer;

forming the first source-drain layer on the interlayer dielectric layer;

forming a passivation layer on the interlayer dielectric layer and the first source-drain layer, the passivation layer is continuously disposed along a bottom portion and sidewall of the first opening, and forms a groove above the first opening;

forming a first planarization layer on the passivation layer, a second opening is formed on a portion of the first planarization layer corresponding to the groove; and

forming the second source-drain layer on the first planarization layer, the third electrode plate is partially formed in the groove.

In a third aspect, a display device is provided, including the display panel as described above.

In the display panel of the embodiments of the present disclosure, the third electrode plate in the second source-drain layer is used as a capacitor electrode, the third electrode plate is extended toward the direction of the second electrode plate, and the third electrode plate is electrically connected to the first electrode plate in the light shielding layer through the conductive electrode in the first source-drain layer, so that the third electrode plate, the second electrode plate and the first electrode plate are overlapped to form a capacitor. Therefore, a metal layer originally used as a capacitor electrode can be saved, so as to simplify the film layer structure of the display panel, and save a mask as well as the corresponding patterning process, thereby improving the manufacturing process yield of the display panel and reducing the production cost of the display panel.

Other features and advantages of the present disclosure will be described in detail in the following detailed description.

### BRIEF DESCRIPTION OF THE DRAWINGS

In order to describe the technical solutions in the embodiments of the present disclosure more clearly, accompanying drawings to be used in the description of the embodiments of the present disclosure will be briefly introduced below. It is apparent that the drawings described below are only some embodiments of the present disclosure, and for those skilled in the art, other drawings can be obtained from these drawings without creative efforts.

In order to fully understand the present disclosure and beneficial effects thereof, the description will be given below in conjunction with the drawings, and the same reference numerals in the description below indicate the same parts in the drawings.

FIG. 1 is a schematic diagram of a structure of a first display panel according to some embodiments of the present disclosure;

FIG. 2 is a schematic diagram of a structure of a second display panel according to some embodiments of the present disclosure;

FIG. 3 is a schematic diagram of a structure of a third display panel according to some embodiments of the present disclosure;

FIG. 4 is a schematic diagram of a structure of a fourth display panel according to some embodiments of the present disclosure;

FIG. 5 is a flowchart of a method for preparing a first display panel according to some embodiments of the present disclosure;

FIGS. 6a to 6d are schematic diagrams of a method for preparing the first display panel according to some embodiments of the present disclosure;

FIG. 7 is a schematic diagram of a structure of a display device according to some embodiments of the present disclosure.

Description of reference numerals:

10. Substrate; 11. Buffer layer; 12. Light shielding layer; 121. First electrode plate 13. Second electrode plate; 14. First source-drain layer; 141. Conductive electrode; 15. Second source-drain layer; 150. Third electrode plate; 151. Body portion; 152. First connecting portion 153. Second connecting portion; 154. Signal bus; 155. Terminal; 16. Capacitor; 17. Passivation layer; 171. Groove; 18. Interlayer dielectric layer; 181. First opening; 19. First planarization layer; 191. Second opening;

20. Second planarization layer; 21. First active layer; 22. First gate insulating layer; 23. Second active layer; 24. Second gate insulating layer; 25. Gate layer; 251. Fourth electrode plate; 26. Anode layer; 27. First pixel definition layer; 28. Second pixel definition layer;

T1. First transistor; T1A. First active portion; T2. Second transistor; T2A. Second active portion;

AA. Display area; GOA. Gate driving circuit area; BA. Bonding area;

100. Display panel; 200. Housing; 1000. Display device.

### DETAILED DESCRIPTION

The technical solutions in the embodiments of the present disclosure will be clearly and completely described below in conjunction with the accompanying drawings in the embodiments of the present disclosure. It is apparent that the embodiments described herein are only some of the embodiments of the present disclosure, but not all of the embodiments of the present disclosure. Based on the embodiments of the present disclosure, all other embodiments obtained by those skilled in the art without making creative efforts fall within the scope of protection of the present disclosure.

The embodiments of the present disclosure provide a display panel. The display panel includes a substrate, a light shielding layer, a second electrode plate, a first source-drain layer, and a second source-drain layer. The light shielding layer is disposed on one side of the substrate, and the light shielding layer includes a first electrode plate. The second electrode plate is disposed on the side of the light shielding layer away from the substrate. The first source-drain layer is disposed on the side of the light shielding layer away from the substrate, and the first source-drain layer includes a conductive electrode. The second source-drain layer is disposed on the side of the first source-drain layer away from the substrate, and the second source-drain layer includes a third electrode plate. The third electrode plate is extended toward the direction of the second electrode plate and is electrically connected to the first electrode plate through the conductive electrode. In the thickness direction of the display panel, the third electrode plate, the second electrode plate and the first electrode plate are overlapped to form a capacitor.

In the display panel of the embodiments of the present disclosure, the third electrode plate in the second source-drain layer is used as a capacitor electrode, the third electrode plate is extended toward the direction of the second electrode plate, and the third electrode plate is electrically connected to the first electrode plate in the light shielding layer through the conductive electrode in the first source-drain layer, so that the third electrode plate, the second electrode plate and the first electrode plate are overlapped to form a capacitor, and a metal layer originally used as a capacitor electrode can be saved, so as to simplify the film layer structure of the display panel, and save a mask as well as the corresponding patterning process, thereby improving the manufacturing process yield of the display panel and reducing the production cost of the display panel.

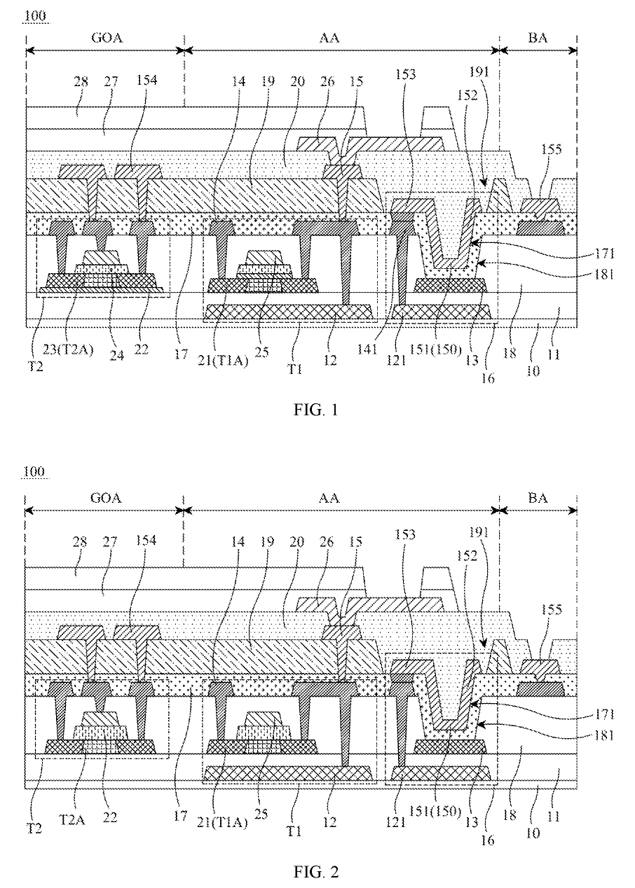

Referring to FIG. 1, and FIG. 1 is a schematic diagram of a structure of a first display panel according to some embodiments of the present disclosure. The display panel 100 includes a substrate 10, a light shielding layer 12, a second electrode plate 13, a first source-drain layer 14, and a second source-drain layer 15. The light shielding layer 12 is disposed on one side of the substrate 10, the light shielding layer 12 includes a first electrode plate 121, and the second electrode plate 13 is disposed on the side of the light shielding layer 12 away from the substrate 10. The first source-drain layer 14 is disposed on the side of the light shielding layer 10 away from the substrate 10, and the first source-drain layer 14 includes a conductive electrode 141. The second source-drain layer 15 is disposed on the side of the first source-drain layer 14 away from the substrate 10, and the second source-drain layer 15 includes a third electrode plate 150. The third electrode plate 150 is extended toward the direction of the second electrode plate 13, and the third electrode plate 150 is electrically connected to the first electrode plate 121 through the conductive electrode 141. In the thickness direction of the display panel, the third electrode plate 150, the second electrode plate 13 and the first electrode plate 121 are overlapped to form a capacitor 16.

It should be noted that in the related art, on the basis of the existing film layer structure, a second gate layer is additionally added on the gate layer, so that the second gate layer can be used as a capacitor electrode to participate in forming a capacitor. In this way, not only will the film layer structure of the display panel become more complicated, but also an additional mask and corresponding manufacturing process will be needed, which will increase the time cost and material cost, and will also lead to a decrease in the yield of the display panel, ultimately leading to an increase in the production cost of the display panel.

In the embodiments of the present disclosure, the third electrode plate 150 in the second source-drain layer 15 is used as a capacitor electrode, the third electrode plate 150 is extended toward the direction of the second electrode plate 13, and the third electrode plate 13 is electrically connected to the first electrode plate 121 in the light shielding layer 12 through the conductive electrode 141 in the first source-drain layer 14, so that the third electrode plate 150, the second electrode plate 13 and the first electrode plate 121 are overlapped to form the capacitor 16. Therefore, a metal layer originally used as a capacitor electrode can be saved, so as to simplify the film layer structure of the display panel, and save a mask as well as the corresponding patterning process, thereby improving the manufacturing process yield of the display panel and reducing the production cost of the display panel.

It should be noted that the third electrode plate 150, the second electrode plate 13 and the first electrode plate 121 being overlapped means that the third electrode plate 150, the second electrode plate 13, and the first electrode plate 121 are respectively disposed in different film layers, and the orthogonal projection of the third electrode plate 150 on the substrate 10, the orthogonal projection of the second electrode plate 13 and the orthogonal projection of the first electrode plate 121 on the substrate 10 are overlapped. This arrangement can not only form the capacitor 16 but also increase the capacitance of the capacitor 16.

In some embodiments, referring to FIG. 1, the display panel 100 further includes a passivation layer 17, and the passivation layer 17 is disposed on the side of the first source-drain layer 14 away from the substrate 10. A portion of the passivation layer 17 corresponding to the second electrode plate 13 is recessed toward the second electrode plate 13 and forms a groove 171, and the third electrode plate 150 is partially disposed in the groove 171.

Referring to FIG. 1, the cross-sectional shape of the groove 171 is an inverted trapezoid. The passivation layer 17 is recessed toward the direction of the second electrode plate 13 to form the groove 171, and the third electrode plate 150 is partially disposed in the groove 171, so that the third electrode plate 150 can be extended toward the direction of the second electrode plate 13, so as to reduce the distance between the third electrode plate 150 and the second electrode plate 13, thereby simplifying the film layer structure of the display panel while optimizing the capacitor structure, which in turn improves the capacitance of the capacitor.

In some embodiments, referring to FIG. 1, the third electrode plate 150 includes a body portion 151, a first connecting portion 152 and a second connecting portion 153. The body portion 151 is disposed at the bottom portion of the groove 171, the first connecting portion 152 is disposed on the sidewall of the groove 171, and the first connecting portion 152 is connected to the body portion 151. The second connecting portion 153 is disposed on the passivation layer 17 at the periphery of the groove 171, one end of the second connecting portion 153 is connected to the first connecting portion 152, and the other end of the second connecting portion 153 is connected to the conductive electrode 141.

In some embodiments, referring to FIG. 1, the body portion 151 acts as a main portion of the third electrode plate 150 participating in forming the capacitor structure. The body portion 151 is tiled on the passivation layer 17 at the bottom portion of the groove 171, and is disposed directly opposite to the second electrode plate 13. The lower surface of the passivation layer 17 is in direct contact with the upper surface of the second electrode plate 13, and the upper surface of the passivation layer 17 is in direct contact with the lower surface of the body portion 151 of the third electrode plate 150. The first connecting portion 152 is inclined and disposed on the sidewall of the groove 171, and the second connecting portion 153 is tiled on the passivation layer 17 at the periphery of the groove 171. In this way, the distance between the third electrode plate 150 and the second electrode plate 13 can be reduced, thereby simplifying the film layer structure of the display panel while optimizing the capacitor structure, which in turn improves the capacitance of the capacitor.

In some embodiments, referring to FIG. 1, the display panel 100 further includes an interlayer dielectric layer 18, the interlayer dielectric layer 18 is partially disposed between the second electrode plate 13 and the first source-drain layer 14. The portion of the interlayer dielectric layer 18 corresponding to the second electrode plate 13 have a first opening 181 formed thereon, the passivation layer 17 is continuously disposed along the bottom portion and the sidewall of the first opening 181, and is recessed above the first opening 181 to form the groove 171.

In some embodiments, referring to FIG. 1, a plurality of first openings 181 are formed on the interlayer dielectric layer 18, and the cross-sectional shape of the first opening 181 is an inverted trapezoid. In the thickness direction of the display panel, the first opening 181 is disposed directly opposite to the second electrode plate 13, the first opening 181 penetrates the interlayer dielectric layer 18, and exposes at least a portion of the upper surface of the second electrode plate 13. A portion of the passivation layer 17 is disposed on the surface of the interlayer dielectric layer 18 away from the substrate, and the other portion of the passivation layer 17 is continuously disposed along the bottom portion and the sidewall of the first opening 181 and is recessed above the first opening 181 to form the groove 171. The first opening 181 is formed on the interlayer dielectric layer 18, and the passivation layer 17 is recessed above the first opening 181 to form the groove 171, so as to reduce the distance between the third electrode plate 150 in the second source-drain layer 15 and the second electrode plate 13 below, thereby simplifying the film layer structure of the display panel while optimizing the capacitor structure, which in turn improves the capacitance of the capacitor.

In some embodiments, referring to FIG. 1, the display panel 100 further includes a first planarization layer 19, the first planarization layer 19 is disposed on the passivation layer 17, and the second source-drain layer 15 is partially disposed on the first planarization layer 19. The portion of the first planarization layer 19 corresponding to the third electrode plate 150 have a second opening 191 formed thereon, the orthographic projection of the third electrode plate 150 on the substrate 10 is in the orthographic projection of the second opening 191 on the substrate 10. Since the manufacturing process of the second source-drain layer 15 is after the manufacturing process of the first planarization layer 19, by disposing the second opening 191 on the first planarization layer 19 and disposing the second opening 191 directly opposite to the first opening 181, the third electrode plate 150 can be formed in the groove 171, thereby simplifying the film layer structure of the display panel while optimizing the capacitance structure, thereby improving the capacitance of the capacitor.

In some embodiments, referring to FIG. 1, along the thickness direction of the first planarization layer 19, the second opening 191 penetrates the first planarization layer 19 and exposes the passivation layer 17 and the groove 171, and the diameter of the second opening 191 or the diameter of the circumscribed circle of the second opening 191 is greater than the diameter of the first opening 181 or the diameter of the circumscribed circle of the first opening 181, so as to facilitate the forming of the third electrode plate 150 on the passivation layer 17 at the bottom portion of the second opening 191.

In some embodiments, referring to FIG. 1, the display panel 100 further includes a second planarization layer 20, the second planarization layer 20 is disposed on the first planarization layer 19 and the second source-drain layer 15, and fills the second opening 191.

In some embodiments, the material of the first planarization layer 19 includes polyimide, and the material of the second planarization layer 20 includes acrylate. By selecting polyimide as the material of the first planarization layer 19, the yield of the half-mask photolithography process can be ensured. By optimizing the material of the second planarization layer 20 and selecting acrylate as the material of the second planarization layer 20, the light sensitivity of the second planarization layer 20 can be improved, and the exposure process time of the second planarization layer 20 can be reduced, thereby not only improving the manufacturing process efficiency, but also improving the flatness of the second planarization layer 20.

In some embodiments, referring to FIG. 1, the display panel 100 further includes a first active layer 21, the first active layer 21 is disposed on the side of the light shielding layer 12 away from the substrate 10, the material of the first active layer 21 includes an oxide semiconductor material, and the first active layer 21 includes the second electrode plate 13. The second electrode plate 13 in the first active layer 21 is selected as the capacitor electrode, which will not increase the film layer structure of the display panel and will not increase the number of masks, and which is beneficial to improving the yield of the display panel and reducing the production cost of the display panel.

In some embodiments, referring to FIG. 1, the display panel 100 further includes a buffer layer 11, a first gate insulating layer 22, a second active layer 23, a second gate insulating layer 24, and a gate layer 25. The buffer layer 11 is disposed on the substrate 10 and the light shielding layer 12, the first active layer 21 and the first gate insulating layer 22 are disposed on the buffer layer 11, the second active layer 23 is disposed on the first gate insulating layer 22 and the second active layer 23, and the gate layer 25 is disposed on the second gate insulating layer 24.

The material of the first active layer 21 includes the oxide semiconductor material, the oxide semiconductor material may be indium gallium zinc oxide. The material of the second active layer 23 includes the silicon semiconductor material, and the silicon semiconductor material may be amorphous silicon or polycrystalline silicon.

In some embodiments, referring to FIG. 1, the display panel 100 includes a display area AA and a gate driving circuit area GOA disposed at the periphery of the display area AA. The gate driving circuit area GOA is provided with a gate driving circuit, the second source-drain layer 15 includes a signal bus 154, and the signal bus 154 is disposed in the gate driving circuit area GOA. By disposing the signal bus 154 above the gate driving circuit in the gate driving circuit area GOA, the frame width of the display panel 100 can be reduced, thereby achieving the effect of narrow frame. On this basis, the third electrode plate of the second source-drain layer 15 is used to form a capacitor with the first electrode plate 121 and the second electrode plate 13, so as to reduce the frame width of the display panel while optimizing the capacitance structure and simplifying the film layer structure of the display panel, and save a mask and the corresponding manufacturing process, thereby improving the manufacturing process yield of the display panel and reducing the production cost of the display panel.

In some embodiments, referring to FIG. 1, the display area AA is provided with a plurality of first transistors T1, and the gate driving circuit includes a plurality of second transistors T2. The first transistor T1 includes a first active portion T1A, and the material of the first active portion T1A includes the silicon semiconductor material. The second transistor T2 includes a second active portion T2A, and the material of the second active part T2A includes the silicon semiconductor material.

In some embodiments, referring to FIG. 1, the first active layer 21 includes the first active portion T1A, and the second active layer 23 includes the second active portion T2A.

In some embodiments, referring to FIG. 1, the bonding area BA is provided with a terminal 155, and the second source-drain layer 15 includes the terminal 155.

In some embodiments, referring to FIG. 1, the display panel 100 is an organic light-emitting diode display panel, and the display panel 100 further includes an anode layer 26, a first pixel definition layer 27, and a second pixel definition layer 28. The anode layer 26 is disposed on the second planarization layer 20, and the first pixel definition layer 27 and the second pixel definition layer 28 are sequentially stacked on the second planarization layer 20 and the anode layer 26.

In some embodiments, the display panel 100 further includes a light-emitting layer, a cathode, and an encapsulation layer (not shown in the figure). It should be noted that FIG. 1 only schematically illustrates the structure of the capacitor in the display panel and does not represent the film layer structure of the display panel 100 in actual applications.

In some other embodiments, the type of the display panel 100 is not limited to the organic light-emitting diode display panel in the embodiments described above, and the display panel 100 may be a liquid crystal display panel or a micro light-emitting diode display panel.

In some embodiments, referring to FIG. 2, and FIG. 2 is a schematic diagram of a structure of a second display panel according to some embodiments of the present disclosure, the structure thereof is substantially the same as the structure of the display panel shown in FIG. 1, and the difference is that: this display panel 100 is provided with the first active layer 21, and the display panel 100 is not provided with the second active layer 23.

Specifically, referring to FIG. 2, the first active layer 21 includes the first active portion T1A and the second active portion T2A, and the materials of the first active portion T1A and the second active portion T2A both include the oxide semiconductor material. That is, the first transistor T1 in the display area AA and the second transistor T2 in the gate driving circuit area GOA are both oxide transistors, so that on the basis of the embodiments shown in FIG. 1, one mask originally required for etching to form the second active layer 23 can be reduced. Therefore, the embodiments shown in FIG. 2 can further simplify the film layer structure of the display panel, and further reduce the production cost of the display panel.

In some embodiments, referring to FIG. 2, the display panel 100 is provided with only one gate insulating layer, that is, the first gate insulating layer 22. The first gate insulating layer 22 is disposed on the first active layer 21, and the gate 25 is disposed on the first gate insulating layer 22.

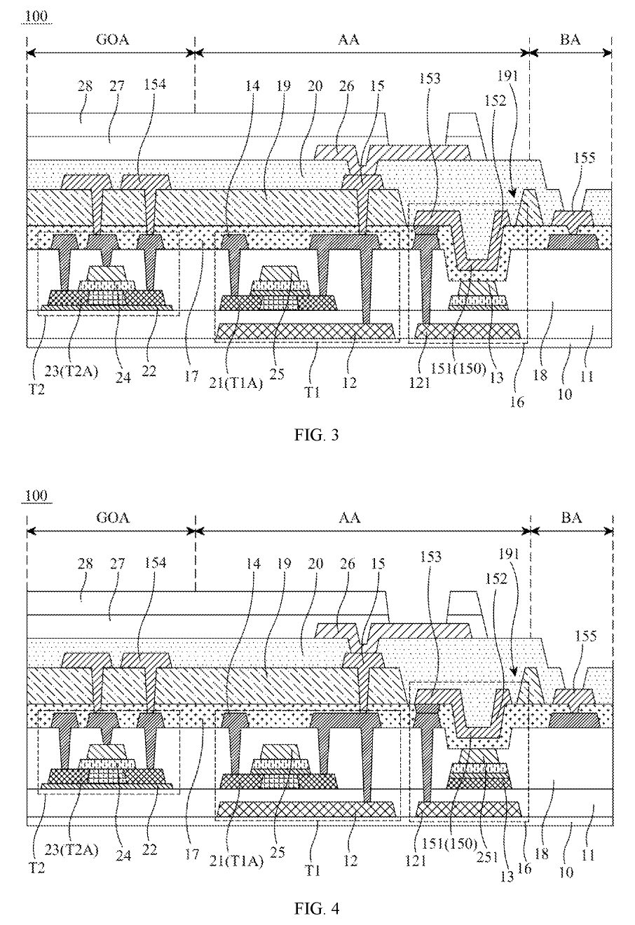

In some embodiments, as shown in FIG. 3, and FIG. 3 is a schematic diagram of a structure of a third display panel according to some embodiments of the present disclosure, the structure thereof is substantially the same as the structure of the display panel shown in FIG. 1, and the difference is that: the gate layer 25 includes the second electrode plate 13.

Specifically, referring to FIG. 3, the gate layer 25 includes the second electrode plate 13, that is, the material of the second electrode plate 13 is the same as that of the gate layer 25, both of which are metal or alloy, and the second electrode plate 13 and the gate layer 25 can share the same mask and be prepared by the same process. Compared with the embodiments shown in FIGS. 1 and 2, the gate layer 25 in the embodiments shown in FIG. 3 is used as the second electrode plate, since the resistance of the metal or alloy is lower than that of the semiconductor material, the capacitance of the capacitor 16 can be further improved.

In some embodiments, referring to FIG. 3, the first gate insulating layer 22 and the second gate insulating layer 24 are partially disposed between the second electrode plate 13 and the first electrode plate 121.

In some embodiments, as shown in FIG. 4, and FIG. 4 is a schematic diagram of a structure of a fourth display panel according to some embodiments of the present disclosure, the structure thereof is substantially the same as the structure of the display panel shown in FIG. 1, and the difference is that: the gate layer 25 includes a fourth electrode plate 251, and the third electrode plate 150, the fourth electrode plate 251, the second electrode plate 13, and the first electrode plate 121 are overlapped to form the capacitor 16. In this way, not only the film layer structure of the display panel can be simplified and the capacitance of the capacitor can be improved, but also a mask and the corresponding patterning process can be saved, thereby improving the manufacturing process yield of the display panel and reducing the production cost of the display panel.

Specifically, referring to FIG. 4, the first active layer 21 includes the second electrode plate 13, and the second electrode plate 13 is disposed on the first electrode plate 121. The fourth electrode plate 251 disposed between the second electrode plate 13 and the third electrode plate 150. The first gate insulating layer 22 and the second gate insulating layer 24 are partially stacked between the second electrode plate 13 and the fourth electrode plate 251, the first gate insulating layer 22 is partially disposed on the surface of the second electrode plate 13 away from the substrate 10, and the fourth electrode plate 251 is disposed on the surface of the second gate insulating layer 24 away from the first gate insulating layer 22.

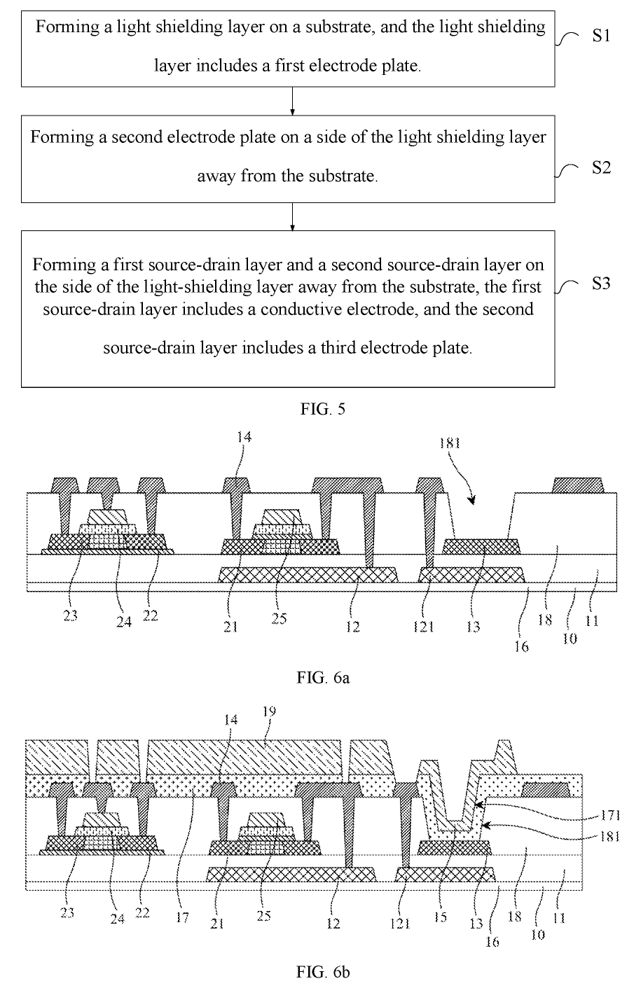

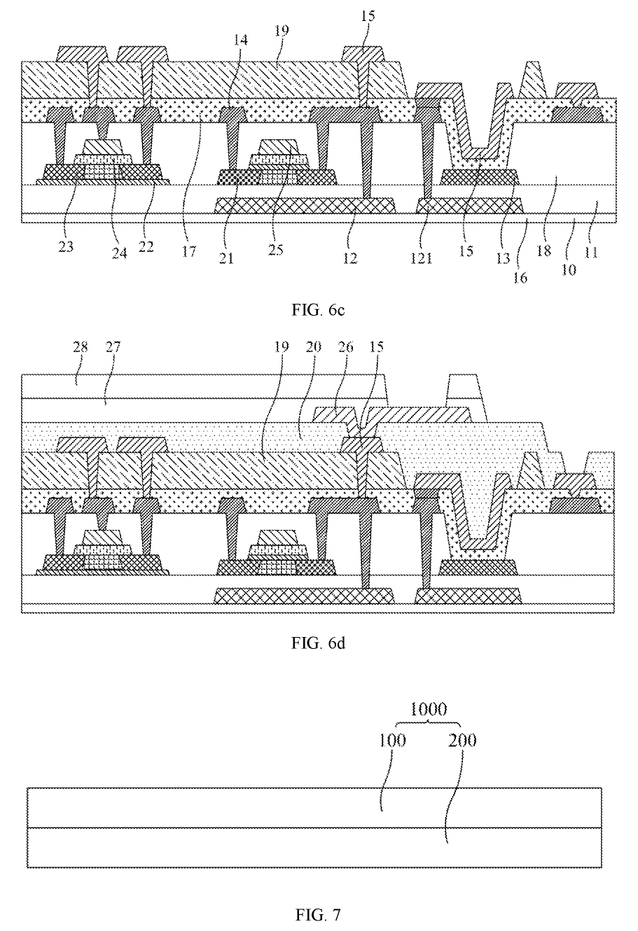

According to the display panel provided by the embodiments of the present disclosure, the embodiments of the present disclosure further provide a method for preparing a display panel for preparing the display panel provided by any one of the embodiments described above. Referring to FIGS. 5 and 6a to 6d, FIG. 5 is a flowchart of a method for preparing a first display panel according to some embodiments of the present disclosure, FIGS. 6a to 6d are schematic diagrams of a method for preparing the first display panel according to some embodiments of the present disclosure, and the method for preparing a display panel includes the following steps.

Step S1, forming a light shielding layer 12 on a substrate 10, and the light shielding layer 12 includes a first electrode plate 121.

Referring to FIG. 6a, the light shielding layer 12 is formed on the substrate 10, and the light shielding layer includes a patterned first electrode plate 121 and a light shielding portion. A buffer layer 11 is further formed on the substrate 10, and the buffer layer 11 covers the light shielding layer 12.

Step S2, forming a second electrode plate 13 on a side of the light shielding layer 12 away from the substrate 10.

Referring to FIG. 6a, step S2 includes the following: a first active layer 21, a first gate insulating layer 22, a second active layer 23, a second gate insulating layer 24, and a gate layer 25 are sequentially formed on the buffer layer 11. The first active layer 21 includes the second electrode plate 13, that is, the second electrode plate 13 and the first active layer 21 are made of the same material, and the second electrode plate 13 and the first active layer 21 are prepared simultaneously by the same process.

Step S3, forming a first source-drain layer 14 and a second source-drain layer 15 on the side of the light-shielding layer 12 away from the substrate 10, the first source-drain layer 14 includes a conductive electrode 141, and the second source-drain layer 15 includes a third electrode plate 150.

Referring to FIGS. 6a, 6b, and 6c, step S3 includes the following. An interlayer dielectric layer 18 is formed on the side of the light shielding layer 12 away from the substrate 10, and a first opening 181 is formed on the interlayer dielectric layer 18. The first source-drain layer 14 is formed on the interlayer dielectric layer 18. A passivation layer 17 is formed on the interlayer dielectric layer 18 and the first source-drain layer 14, the passivation layer 17 is continuously disposed along the bottom portion and sidewall of the first opening 181, and the passivation layer is recessed above the first opening 181 to form a groove 171. A first planarization layer 19 is formed on the passivation layer 17, and a portion of the first planarization layer 19 corresponding to the groove 171 have a second opening 191 formed thereon. A second source-drain layer 15 is formed on the first planarization layer 19, and the third electrode plate 150 is partially formed in the groove 171.

Referring to FIG. 6c, the third electrode plate 150 is extended toward the direction of the second electrode plate 13, the third electrode plate 150 is electrically connected to the first electrode plate 121 through the conductive electrode 141. In the thickness direction of the display panel, the third electrode plate 150, the second electrode plate 13 and the first electrode plate 121 are overlapped to form a capacitor.

In some embodiments, referring to FIG. 6d, the method for preparing the display panel further includes step S4: sequentially forming an anode layer 26, a first pixel definition layer 27, a second pixel definition layer 28, a light-emitting layer, a cathode layer, and an encapsulation layer (not shown in the figure) on the first planarization layer 19 and the second source-drain layer 15.

According to the display panel provided by the embodiments of the present disclosure, the embodiments of the present disclosure further provide a display device. Referring to FIG. 7, and FIG. 7 is a schematic diagram of a structure of display device according to some embodiments of the present disclosure. The display device 1000 includes a display panel 100 and a housing 200, and the display panel 100 is disposed on the housing 200. The display device 1000 may include the display panel provided in any of the above embodiments. The display device provided by the embodiments of the present disclosure can achieve the same technical effect as the display panel provided by any one of the embodiments described above, and which will not be described herein again.

The beneficial effects of the embodiments of the present disclosure are that: the embodiments of the present disclosure provide a display panel, a method for preparing a display panel, and a display device. The display panel includes a substrate, a light shielding layer, a second electrode plate, a first source-drain layer and a second source-drain layer. The light shielding layer includes a first electrode plate, the first source-drain layer includes a conductive electrode, the second source-drain layer is disposed on a side of the first source-drain layer away from the substrate, and the second source-drain layer includes a third electrode plate. The third electrode plate in the second source-drain layer is used as a capacitor electrode, the third electrode plate is extended toward the direction of the second electrode plate, and the third electrode plate is electrically connected to the first electrode plate in the light shielding layer through the conductive electrode in the first source-drain layer, so that the third electrode plate, the second electrode plate and the first electrode plate are overlapped to form a capacitor. Therefore, a metal layer originally used as a capacitor electrode can be saved, so as to simplify the film layer structure of the display panel, and save a mask as well as the corresponding patterning process, thereby improving the manufacturing process yield of the display panel and reducing the production cost of the display panel.

In the description of the present disclosure, the terms “first”, “second” and the like are used for descriptive purposes only and are not to be construed as indicating or implying relative importance or implying an amount of indicated technical features. Thus, features defined with “first” and “second” may explicitly or implicitly include one or more of the features. In the description of the present disclosure, the term “a plurality of” refers to two or more unless otherwise specifically defined.

In the above embodiments, each embodiment is described with its own emphasis. For parts that are not described in detail in a certain embodiment, reference can be made to the relevant descriptions of other embodiments.

The embodiments, implementations and related technical features of the present disclosure can be combined and replaced with each other without conflict.

The above embodiments are merely preferred embodiments of the present disclosure, and do not limit the present disclosure in any form. Any simple modification, equivalent change and embellishment to the above embodiments based on the technical essence of the present disclosure without departing from the content of the technical solution of the present disclosure still fall within the scope of the technical solution of the present disclosure.

What is claimed is:

1. A display panel comprising:
a substrate;
a light shielding layer disposed on one side of the substrate, wherein the light shielding layer comprises a first electrode plate;
a second electrode plate disposed on a side of the light shielding layer away from the substrate;
a first source-drain layer disposed on the side of the light shielding layer away from the substrate, wherein the first source-drain layer comprises a conductive electrode; and
a second source-drain layer disposed on a side of the first source-drain layer away from the substrate;
wherein the second source-drain layer comprises a third electrode plate, the third electrode plate is extended toward a direction of the second electrode plate, the third electrode plate is electrically connected to the first electrode plate through the conductive electrode, and along a thickness direction of the display panel, the third electrode plate, the second electrode plate and the first electrode plate are overlapped to form a capacitor.

2. The display panel according to claim 1, wherein the display panel further comprises a passivation layer, the passivation layer is disposed on the side of the first source-drain layer away from the substrate, a portion of the passivation layer corresponding to the second electrode plate is recessed toward the direction of the second electrode plate and forms a groove, and the third electrode plate is partially disposed in the groove.

3. The display panel according to claim 2, wherein the third electrode plate comprises:
a body portion disposed at a bottom portion of the groove;
a first connecting portion disposed on a sidewall of the groove, wherein the first connecting portion is connected to the body portion; and
a second connecting portion disposed on the passivation layer at a periphery of the groove, wherein one end of the second connecting portion is connected to the first connecting portion, and another end of the second connecting portion is connected to the conductive electrode.

4. The display panel according to claim 2, wherein the display panel further comprises an interlayer dielectric layer, the interlayer dielectric layer is partially disposed between the second electrode plate and the first source-drain layer, a first opening is formed on a portion of the interlayer dielectric layer corresponding to the second electrode plate, the passivation layer is continuously disposed along a bottom portion and a sidewall of the first opening, and is recessed above the first opening to form the groove.

5. The display panel according to claim 4, wherein the display panel further comprises a first planarization layer, the first planarization layer is disposed on the passivation layer, and the second source-drain layer is partially disposed on the first planarization layer;
wherein a second opening is formed on a portion of the first planarization layer corresponding to the third electrode plate, and an orthographic projection of the third electrode plate on the substrate is in an orthographic projection of the second opening on the substrate.

6. The display panel according to claim 5, wherein the display panel further comprises a second planarization layer, the planarization layer is disposed on the first planarization layer and the second source-drain layer, and fills the second opening.

7. The display panel according to claim 6, wherein a material of the first planarization layer comprises polyimide, and a material of the second planarization layer comprises acrylate.

8. The display panel according to claim 1, wherein the display panel further comprises a first active layer, the first active layer is disposed on the side of the light shielding layer away from the substrate, a material of the first active layer comprises an oxide semiconductor material, and the first active layer comprises the second electrode plate.

9. The display panel according to claim 1, wherein the display panel further comprises:
a first active layer disposed on the side of the light shielding layer away from the substrate, and a material of the first active layer comprises an oxide semiconductor material; and
a gate layer disposed on a side of the first active layer away from the substrate, wherein the gate layer comprises the second electrode plate.

10. The display panel according to claim 9, wherein the display panel further comprises:
a first gate insulating layer disposed on the substrate and the first active layer;
a second active layer disposed on the first gate insulating layer, wherein a material of the second active layer comprises a silicon semiconductor material; and
a second gate insulating layer disposed on the first gate insulating layer and the second active layer, wherein the gate layer is disposed on the second gate insulating layer;
wherein the first gate insulating layer and the second gate insulating layer are partially disposed between the second electrode plate and the first electrode plate.

11. The display panel according to claim 1, wherein the display panel further comprises:
a first active layer disposed on the side of the light shielding layer away from the substrate, and the first active layer comprises the second electrode plate; and
a gate layer disposed on a side of the first active layer away from the substrate, wherein the gate layer comprises a fourth electrode plate, and along a thickness direction of the display panel, the third electrode plate, the fourth electrode plate, the second electrode plate, and the first electrode plate are overlapped to form the capacitor.

12. The display panel according to claim 11, wherein the display panel further comprises:
a first gate insulating layer disposed on the substrate and the first active layer;
a second active layer disposed on the first gate insulating layer; and
a second gate insulating layer disposed on the first gate insulating layer and the second active layer, wherein the gate layer is disposed on the second gate insulating layer;
wherein the first gate insulating layer and the second gate insulating layer are partially disposed between the second electrode plate and the fourth electrode plate.

13. The display panel according to claim 1, wherein the display panel comprises a display area and a gate driving circuit area disposed at a periphery of the display area, the gate driving circuit area is provided with a gate driving circuit, the second source-drain layer comprises a signal bus, and the signal bus is disposed in the gate driving circuit area.

14. The display panel according to claim 13, wherein the display area is provided with a plurality of first transistors, and the gate driving circuit comprises a plurality of second transistors;
wherein each of the plurality of first transistors comprises a first active portion, and a material of the first active portion comprises an oxide semiconductor material; each of the plurality of second transistor comprises a second active portion, and a material of the second active portion comprises an oxide semiconductor material or a silicon semiconductor material.

15. A method for preparing a display panel, wherein the display panel comprises:
a substrate;
a light shielding layer disposed on one side of the substrate, wherein the light shielding layer comprises a first electrode plate;
a second electrode plate disposed on a side of the light shielding layer away from the substrate;
a first source-drain layer disposed on the side of the light shielding layer away from the substrate, wherein the first source-drain layer comprises a conductive electrode; and
a second source-drain layer disposed on a side of the first source-drain layer away from the substrate;
wherein the second source-drain layer comprises a third electrode plate, the third electrode plate is extended toward a direction of the second electrode plate, the third electrode plate is electrically connected to the first electrode plate through the conductive electrode, and along a thickness direction of the display panel, the third electrode plate, the second electrode plate and the first electrode plate are overlapped to form a capacitor; and
the method for preparing a display panel comprises following steps:
forming the light shielding layer on the substrate, and the light shielding layer comprises the first electrode plate;
forming the second electrode plate on the side of the light shielding layer away from the substrate; and
forming the first source-drain layer and the second source-drain layer on the side of the light-shielding layer away from the substrate, the first source-drain layer comprises the conductive electrode, and the second source-drain layer comprises the third electrode plate;
wherein the third electrode plate is extended toward the direction of the second electrode plate, the third electrode plate is electrically connected to the first electrode plate through the conductive electrode, and along the thickness direction of the display panel, the third electrode plate, the second electrode plate and the first electrode plate are overlapped to form the capacitor.

16. The method for preparing a display panel according to claim 15, wherein forming the first source-drain layer and the second source-drain layer on the side of the light-shielding layer away from the substrate comprises following steps:
forming an interlayer dielectric layer on the side of the light shielding layer away from the substrate, wherein a first opening is formed on the interlayer dielectric layer;
forming the first source-drain layer on the interlayer dielectric layer;
forming a passivation layer on the interlayer dielectric layer and the first source-drain layer, wherein the passivation layer is continuously disposed along a bottom portion and sidewall of the first opening, and forms a groove above the first opening;
forming a first planarization layer on the passivation layer, wherein a second opening is formed on a portion of the first planarization layer corresponding to the groove; and
forming the second source-drain layer on the first planarization layer, wherein the third electrode plate is partially formed in the groove.

17. A display device comprising a display panel, wherein the display panel comprises:
a substrate;
a light shielding layer disposed on one side of the substrate, wherein the light shielding layer comprises a first electrode plate;
a second electrode plate disposed on a side of the light shielding layer away from the substrate;
a first source-drain layer disposed on the side of the light shielding layer away from the substrate, wherein the first source-drain layer comprises a conductive electrode; and
a second source-drain layer disposed on a side of the first source-drain layer away from the substrate;
wherein the second source-drain layer comprises a third electrode plate, the third electrode plate is extended toward a direction of the second electrode plate, the third electrode plate is electrically connected to the first electrode plate through the conductive electrode, and along a thickness direction of the display panel, the third electrode plate, the second electrode plate and the first electrode plate are overlapped to form a capacitor.

18. The display device according to claim 17, wherein the display panel further comprises a passivation layer, the passivation layer is disposed on the side of the first source-drain layer away from the substrate, a portion of the passivation layer corresponding to the second electrode plate is recessed toward the direction of the second electrode plate and forms a groove, and the third electrode plate is partially disposed in the groove.

19. The display device according to claim 18, wherein the third electrode plate comprises:
a body portion disposed at a bottom portion of the groove;
a first connecting portion disposed on a sidewall of the groove, wherein the first connecting portion is connected to the body portion; and
a second connecting portion disposed on the passivation layer at a periphery of the groove, wherein one end of the second connecting portion is connected to the first connecting portion, and another end of the second connecting portion is connected to the conductive electrode.

20. The display device according to claim 18, wherein the display panel further comprises an interlayer dielectric layer, the interlayer dielectric layer is partially disposed between the second electrode plate and the first source-drain layer, a first opening is formed on a portion of the interlayer dielectric layer corresponding to the second electrode plate, the passivation layer is continuously disposed along a bottom portion and a sidewall of the first opening, and is recessed above the first opening to form the groove.
